(19) United States
(12) Patent Application Publication
(10) Pub. No.: US 2013/0257442 A1
(43) Pub. Date: Oct. 3, 2013

(54) POWER SOURCE DETECTION CIRCUIT AND ELECTRONIC DEVICE WITH POWER SOURCE DETECTION CIRCUIT

(71) Applicant: XING-HUA TANG, Shenzhen City (CN)

(72) Inventor: XING-HUA TANG, Shenzhen City (CN)

(21) Appl. No.: 13/629,483

(22) Filed: Sep. 27, 2012

(30) Foreign Application Priority Data
Apr. 3, 2012 (CN) 201210095713.1

(51) Int. Cl. G01R 31/36

(52) U.S. Cl. 324/428

(57) ABSTRACT

A power source detection circuit includes a voltage conversion module and a signal producing module. The voltage conversion module is connected to a power port, and is used to convert a voltage of a power source to a detection voltage. The signal producing module is connected to the voltage conversion module and a processing unit, and is used to compare the detection voltage with a reference voltage, and produces a high voltage signal to trigger the processing unit to control to display a remaining power of the battery when determining the detection voltage is lower than the reference voltage. The signal producing module is also used to produce a low voltage signal to trigger the processing unit to not display the remaining power of the battery when determining the detection voltage is higher than the reference voltage.

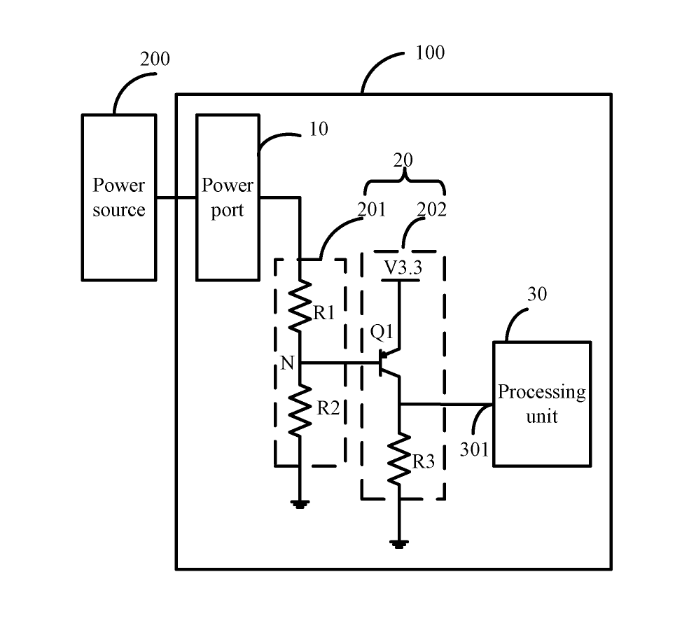

### BACKGROUND

1. Technical Field

The present disclosure relates to circuits and, particularly, to a power source detection circuit and an electronic device with the power source detection circuit.

2. Description of Related Art

Electronic devices, such as mobile phones, digital cameras, and electronic readers, can be powered by a battery or an external power source, such as a power adapter. When the electronic device is powered by the battery, there is need to display the remaining power of the battery usually, when the electronic device is powered by the power adapter, there is no need to display the remaining power of the power source. However, it is needed to provide a detection circuit to detect whether the electronic device is powered by a battery or the power adapter and to display the remaining power of the battery in case the battery is used.

However, the common detection circuit is complex. A new power source detection circuit and an electronic device with the power source detection circuit, to overcome the described limitations, is thus needed.

### BRIEF DESCRIPTION OF THE DRAWINGS

Many aspects of the present disclosure are better understood with reference to the following drawing. The components in the drawing are not necessarily drawn to scale, the emphasis instead being placed upon clearly illustrating the principles of the present disclosure. Moreover, in the drawing, like reference numerals designate corresponding parts throughout the view.

The FIGURE is a circuit diagram of an electronic device with a power source detection, in accordance with an exemplary embodiment.

### DETAILED DESCRIPTION

Embodiments of the present disclosure will be described with reference to the accompanying drawings.

The FIGURE illustrates an electronic device 100 of the embodiment. The electronic device 100 includes a power port 10, a power source detection circuit 20, and a processing unit 30.

The power port 10 is used to connect a power source 200. In the embodiment, the power source 200 can be a power adapter or a battery.

The power source detection circuit 20 includes a voltage conversion module 201 and a signal producing module 202. The voltage conversion module 201 is used to convert a voltage of the power source 200 connected to the power port 10 to a detection voltage. In the embodiment, the detection voltage is proportional to the voltage of the power source 200. The signal producing module 202 is connected to the voltage conversion module 201 and the processing unit 30, and is used to compare the detection voltage with a reference voltage. The signal producing module 202 produces a high voltage signal when determining the detection voltage is less than the reference voltage, and produces a low voltage signal when determining the detection voltage is greater than the reference voltage.

The processing unit 30 determines the power source 200 is a battery and controls to display the remaining power of the battery, when receiving the high voltage signal from the signal producing module 202. The processing unit 30 determines the power source 200 is a power adapter, and controls not to display the remaining power of the battery, when receiving the low voltage signal from the signal producing module 202.

In detail, the voltage conversion module 201 includes a first resistor R1 and a second resistor R2. The first resistor R1 and the second resistor R2 are connected between the power port 10 and ground in series. When the power port 10 is connected to the power source 200, the voltage of the power source 200 is divided by the first resistor R1 and the second resistor R2. A connection node N of the first resistor R1 and the second resistor R2 constitutes an output port of the voltage conversion module 201 and outputs the detection voltage accordingly. In the embodiment, the voltage of the second resistor R2 is the detection voltage.

The signal producing module 202 includes a positive-negative-positive bipolar junction transistor (pnp BJT) and a third resistor R3. An emitter of the pnp BJT Q1 is connected to a voltage port V3.3, a collector of the pnp BJT Q1 is grounded via the third resistor R3, a base of the pnp BJT Q1 is connected to the connection node N of the first resistor R1 and the second resistor R2. In another embodiment, the pnp BJT Q1 can be replaced by a P-channel metal-oxide-semiconductor field-effect transistor.

In the embodiment, the voltage port V3.3 provides the reference voltage. In more detail, the voltage port V3.3 is connected to a voltage regulator (not shown) which produces a constant reference voltage. The processing unit 30 includes a detection pin 301. The collector of the pnp BJT Q1 is also connected to the detection pin 301 of the processing unit 30.

In the embodiment, the resistance values of the first resistor R1 and the second R2 is preset to ensure the detection voltage is higher than the reference voltage when the power port 10 connects to the power adapter, and make the detection voltage lower than the reference voltage when the power port 10 connects to the battery. For example, as is known, the voltage of the power adapter is usual 12 volt (V), the voltage of the battery is usually 6V-8V. If the resistance value of the first resistor R1 is 130 ohm, the resistance value of the second resistor R2 is 51 ohm, and the reference voltage is 3.3 V, then when the power port 10 connects to the power adapter. The voltage of the connection node N, namely the conversion voltage is 12*51/(51+130)=3.38 V, which is higher than the reference voltage. When the power port 10 connects to the battery, the voltage of the connection node N, namely the conversion voltage is between 6*51/(51+130)=1.69 V to 8*51/(51+130)=2.254 V, which is lower than the reference voltage.

Therefore, when the power source 200 connected to the power port 10 is the power adapter, the voltage of the base of the pnp BJT Q1 is higher than the voltage of the emitter of the pnp BJT Q1, and then the pnp BJT Q1 is turned off accordingly. The collector of the pnp BJT Q1 is grounded via the third resistor R3 and is at a low voltage. The detection pin 301 of the processing unit 30 is connected to the collector of the pnp BJT Q1 and obtains the low voltage signal. The processing unit 30 then does not display the remaining power of the battery when receiving the low voltage signal.

When the power source 200 connected to the power port 10 is the battery, the voltage of the base of the pnp BJT Q1 is lower than the voltage of the emitter of the pnp BJT Q1, then the pnp BJT Q1 is turned on accordingly. The collector of the pnp BJT Q1 is electronically connected to the voltage port V3.3 via the pnp BJT, which is turned on and at a high voltage. The detection pin 301 of the processing unit 30 then obtains the high voltage signal. The processing unit 30 then controls to display the remaining power of the battery when receiving the high voltage signal.

In the embodiment, the electronic device 100 can be a mobile phone, a digital camera, a digital photo frame, an electronic reader, for example.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being exemplary embodiments of the present disclosure.

What is claimed is:

1. A power source detection circuit comprising:
a voltage conversion module connected to a power port, configured to convert a voltage of a power source connected to the power port to a detection voltage proportional to the voltage of the power source, wherein, the power source is one of a power adapter and a battery; and
a signal producing module connected to the voltage conversion module and a processing unit, configured to compare the detection voltage with a reference voltage, and produces a high voltage signal to trigger the processing unit to control to display a remaining power of the battery, when determining the detection voltage is lower than the reference voltage, and produces a low voltage signal to trigger the processing unit to control not to display the remaining power of the battery, when determining the detection voltage is higher than the reference voltage.

2. The power source detection circuit according to claim 1, wherein the voltage conversion module comprises a first resistor and a second resistor which are connected between the power port and ground in series, the voltage of the power source is divided by the first resistor and the second resistor, and a connection node of the first resistor and the second resistor outputs the detection voltage accordingly.

3. The power source detection circuit according to claim 2, wherein the signal producing module comprises a P-channel metal-oxide-semiconductor field-effect transistor (pnp BJT) and a third resistor, an emitter of the pnp BJT is connected to a voltage port providing the reference voltage, a collector of the pnp BJT is grounded via the third resistor and is further connected to the processing unit, a base of the pnp BJT is connected to the connection node of the first resistor and the second resistor.

4. The power source detection circuit according to claim 3, wherein resistance values of the first resistor and the second are preset to ensure the detection voltage is higher than the reference voltage when the power source connected to the power port is the power adapter, and ensure the detection voltage is lower than the reference voltage when the power source connected to the power port is the battery.

5. The power source detection circuit according to claim 4, wherein when the power port connects to the power adapter, a voltage of the base of the pnp BJT connected to the connection node is equal to the detection voltage and is higher than the reference voltage, then the pnp BJT is turned off, the collector of the pnp BJT is grounded via the third resistor and is at a low voltage, then the signal producing module outputs the low voltage signal to the processing unit.

6. The power source detection circuit according to claim 4, wherein when the power port connects to the battery, a voltage of the base of the pnp BJT connected to the connection node is equal to the detection voltage and is lower than the reference voltage, then the pnp BJT is turned on, the collector of the pnp BJT is electronically connected to the voltage port via the pnp BJT which is turned on and then is at a high voltage, then the signal producing module outputs the high voltage signal to the processing unit.

7. An electronic device comprising:
a power port, configured to connect to a power source, wherein, the power source is one of a power adapter and a battery;
a processing unit; and
a power source detection circuit comprising:
a voltage conversion module connected to the power port, configured to convert a voltage of the power source connected to the power port to a detection voltage proportional to the voltage of the power source; and
a signal producing module connected to the voltage conversion module and a processing unit, configured to compare the detection voltage with a reference voltage, and produce a high voltage signal when determining the detection voltage is lower than the reference voltage; and produce a low voltage signal when determining the detection voltage is higher than the reference voltage;
wherein, the processing unit controls to display a remaining power of the battery when receiving the high voltage signal, and controls not to display the remaining power of the battery when receiving the low voltage signal.

8. The electronic device according to claim 7, wherein the voltage conversion module comprises a first resistor and a second resistor which are connected between the power port and ground in series, the voltage of the power source is divided by the first resistor and the second resistor, and a connection node of the first resistor and the second resistor outputs the detection voltage accordingly.

9. The electronic device according to claim 8, wherein the signal producing module comprises a P-channel metal-oxide-semiconductor field-effect transistor (pnp BJT) and a third resistor, an emitter of the pnp BJT is connected to a voltage port providing the reference voltage, a collector of the pnp BJT is grounded via the third resistor and is further connected to the processing unit, a base of the pnp BJT is connected to the connection node of the first resistor and the second resistor.

10. The electronic device according to claim 9, wherein resistance values of the first resistor and the second are preset to ensure the detection voltage is higher than the reference voltage when the power source connected to the power port is the power adapter, and ensure the detection voltage is lower than the reference voltage when the power source connected to the power port is the battery.

11. The electronic device according to claim 10, wherein when the power port connects to the power adapter, a voltage of the base of the pnp BJT connected to the connection node is equal to the detection voltage and is higher than the reference voltage, then the pnp BJT is turned off, the collector of the pnp BJT is grounded via the third resistor and is at a low voltage, then the signal producing module outputs the low voltage signal.

12. The electronic device according to claim 11, wherein when the power port connects to the battery, a voltage of the base of the pnp BJT connected to the connection node is equal to the detection voltage and is lower than the reference voltage, then the pnp BJT is turned on, the collector of the pnp BJT is electronically connected to the voltage port via the pnp BJT which is turned on and then is at a high voltage, then the signal producing module outputs the high voltage signal.

13. The electronic device according to claim 9, wherein the processing unit comprises a detection pin, the detection pin is connected to the collector of the pnp BJT, collector of the pnp BJT, when the detection pin receives the high voltage signal, the processing unit controls to display a remaining power of the battery, and when the detection pin receives the low voltage signal, the processing unit controls not to display the remaining power of the battery.

14. The electronic device according to claim 7, wherein the electronic device is one selected from a group consist of a mobile phone, a digital camera, a digital photo frame, and an electronic reader.
